(19) United States
(12) Patent Application Publication
(10) Pub. No.: US 2012/0286402 A1
(43) Pub. Date: Nov. 15, 2012

(54) PROTUBERANT STRUCTURE AND METHOD FOR MAKING THE SAME

(76) Inventors: Chin-Te Kuo, New Taipei City (TW); Yi-Nan Chen, Taipei City (TW); Hsien-Wen Liu, Taoyuan County (TW)

(21) Appl. No.: 13/105,910

(22) Filed: May 12, 2011

(51) Int. Cl. H01L 29/06; H01L 21/302; H01L 23/48

(52) U.S. Cl. 257/623; 257/737; 438/701; 257/E23.01; 257/E29.022; 257/E21.214

(57) ABSTRACT

A cuboidal protuberant structure is provided. The cuboidal protuberant structure includes a substrate and a protrusion disposed on the substrate. The protrusion has a vertical side wall with a rounded corner, a protuberant width and a protuberant length. At least one of the protuberant width and the protuberant length is not greater than 33 nm.

### BACKGROUND OF THE INVENTION

1. Field of the Invention

The present invention generally relates to a protuberant structure and a method for forming a protuberant structure. In particular, the present invention is directed to a cuboidal protuberant structure which has an extremely small dimension beyond the capability of the current photolithographic technique on a substrate and a method for forming such cuboidal protuberant structure.

2. Description of the Prior Art

During the process of fabricating silicon based memory chips, there are usually multiple photolithographic process steps involved. In each of these steps, a particular pattern with certain fixed dimensions is printed on the wafer. After all of the particular patterns are processed, a complete working circuit is accordingly created.

As a consequence of many factors, including the demands for portability, function, capacity and efficiency, integrated circuits are continuously being reduced in size but the pattern features, such as conductive lines are still usually formed by photolithography. The concept of pitch is used to describe the sizes of these features. Pitch is defined as the distance between identical points in two neighboring features of a repeating pattern. However, due to factors such as optical or physical phenomenon, conventional photolithographic techniques have a minimum size limitation beyond which a photolithographic technique fails to reliably form desirable features of a smaller pitch. Thus, the minimum pitch which a photolithographic technique can reliably define is an obstacle to the ongoing reduction of feature sizes.

As the dimensions of the semiconductor device are getting smaller and smaller, the current solution to requirements of a smaller critical dimension is to upgrade the photolithographic tools or to employ a new type laser writer. However, both solutions are extremely expensive and not cost-efficient.

### SUMMARY OF THE INVENTION

The present invention in a first aspect proposes a cuboidal protuberant structure which has an extremely small dimension beyond the capability of the current photolithographic technique on a substrate. The cuboidal protuberant structure of the present invention includes a substrate and a protrusion disposed on the substrate. The protrusion has a vertical side wall with a rounded corner, a protuberant width and a protuberant length. At least one of the protuberant width and the protuberant length is not greater than 33 nm.

In one embodiment of the present invention, the protrusion includes a metal, a semi-conductive material or an insulating material.

In another embodiment of the present invention, the protuberant length is at least 1 time greater than the protuberant width.

In another embodiment of the present invention, the protuberant length approximately equals the protuberant width

In another embodiment of the present invention, the protrusion has a protuberant height at least half less than the protuberant width.

In another embodiment of the present invention, the protrusion forms a gate structure.

In another embodiment of the present invention, the protrusion forms a MEMS (microelectromechanical structure).

The present invention in a second aspect proposes a method for forming a protuberant structure which has an extremely small dimension beyond the capability of the current photolithographic techniques on a substrate. First, a substrate and a plurality of tapered structures disposed on the substrate are provided. The tapered structures include a first material disposed on the substrate and are segregated by a pre-determined distance. Second, a target layer of a second material is formed to cover the substrate and the tapered structures. The first material and the second material are substantially different. Next, an etching step is carried out to partially remove the target layer in order to expose the tapered structures. Later, a trimming step is carried out to completely remove the tapered structures and to partially remove the target layer to form a cuboidal protrusion. The cuboidal protrusion has a vertical side wall with a rounded corner, a protuberant width and a protuberant length. The target layer is more susceptible to the trimming step than the tapered structures. At least one of the protuberant width and the protuberant length is not greater than 33 nm.

In one embodiment of the present invention, the protrusion may include a metal, a semi-conductive material or an insulating material.

In another embodiment of the present invention, the protuberant length is at least 1 time greater than the protuberant width.

In another embodiment of the present invention, the protuberant length approximately equals the protuberant width.

In another embodiment of the present invention, the cuboidal protrusion has a protuberant height at least half less than the protuberant width.

In another embodiment of the present invention, the method of the present invention further includes some additional steps. For example, first a layer of the first material is formed on the substrate. Second, the first material is partially removed by a first material etching step in the presence of a mask to form at least one recess which has an opening greater than the bottom of the recess and is disposed between the tapered structures.

In another embodiment of the present invention, the width of the bottom of the recess is not greater than 33 nm.

In another embodiment of the present invention, the width of the bottom of the recess is greater than the protuberant width.

In another embodiment of the present invention, the method of the present invention further includes some additional steps. For example, a cap layer of a third material is formed to cover the tapered structures. The first material, the second material and the third material are mutually different. Next, the trimming step is carried out to completely remove the cap layer.

In another embodiment of the present invention, the cap layer may have a thickness around 5 nm.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate the method for forming the protuberant structure of the present invention.

FIGS. 8 and 9 illustrate the protuberant structure of the present invention.

### DETAILED DESCRIPTION

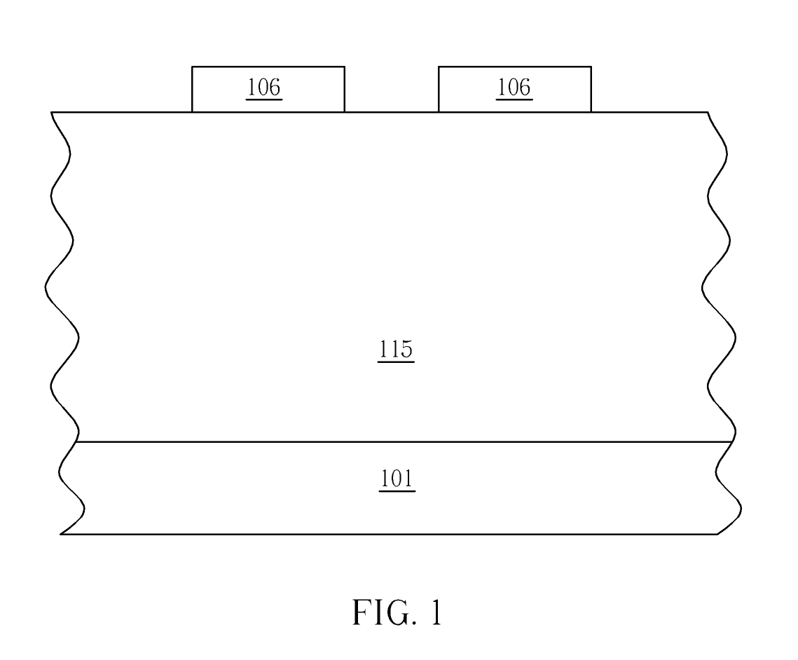

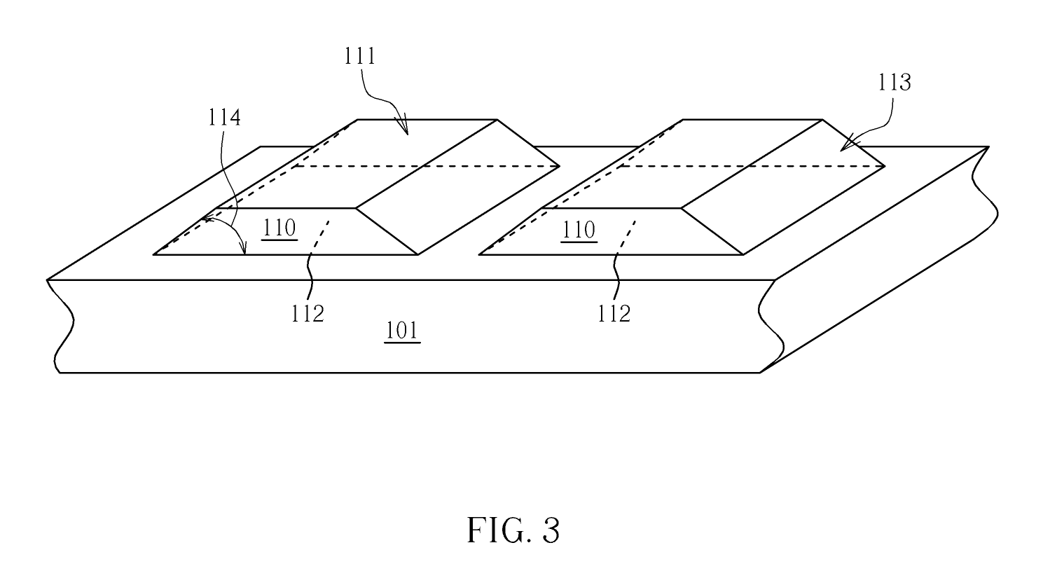

The present invention first provides a method for forming a protuberant structure. The protuberant structure in particular has an extremely small dimension which is not usually able to be formed by conventional photolithographic techniques. Please refer to FIGS. 1-8, which illustrate the method for forming the protuberant structure of the present invention. First, as shown in FIG. 3, a substrate 101 and a plurality of tapered structures 110 disposed on the substrate 101 are provided. The substrate 101 maybe a semi-conductive material, such as Si, and the tapered structures 110 may include a first material such as an oxide. The tapered structures 110 are in a form of a trapezoid and have a top side 111, a bottom side 112 and a tapered side wall 113. The tapered side wall 113 is disposed between the top side 111 and the bottom side 112. The tapered structures 110 of the present invention may be formed by the procedures as follows.

Please refer to FIG. 1, first a basic layer 115 is formed on the substrate 101. The basic layer 115 usually includes an oxide. Then, a patterned mask 116 is formed on the basic layer 115, such as by a conventional photolithographic method. Depending on the specifications of the final structure, the mask 116 may have different patterns. However, the pitch of two adjacent mask region of the mask 116 is preferably as small as possible.

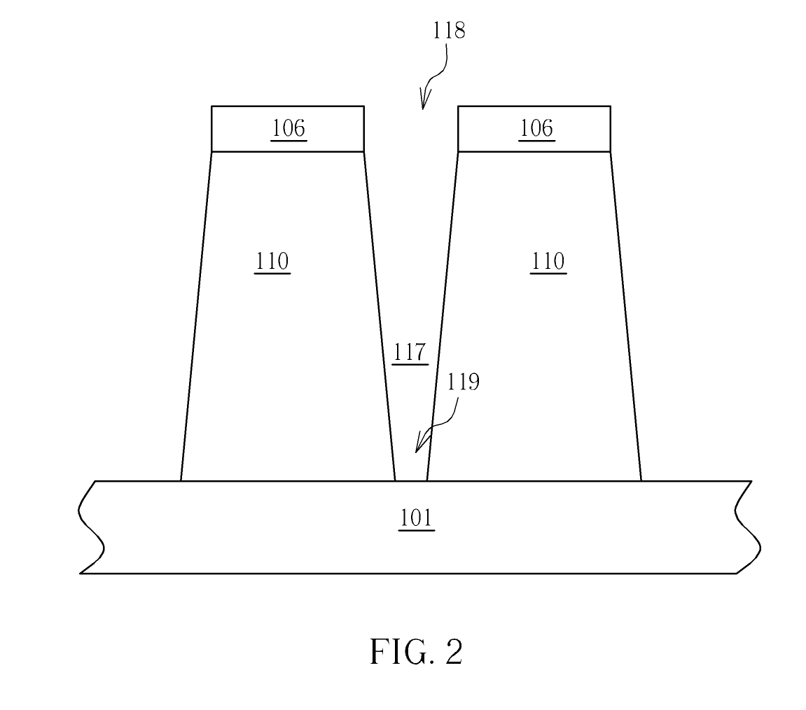

Second, please refer to FIG. 2, a first material etching step is carried out to partially remove the first material of the basic layer 115 and to partially expose the substrate 101 in order to form the recess 117 disposed between the tapered structures 110. The recipe of the first material etching step is specially formulated, such as a high polymer etching step, to protect the side of the recess 117 of the basic layer 115 so that the recess 117 preferably has a bottom part 119 substantially smaller than the opening 118. The bottom part 119 may be more or less as wide as 33 nm. The recipe of the first material etching step may be a high selectivity etch recipe.

After the first material etching step is complete, the patterned mask 116 is removed to obtain the tapered structures 110 in a form of an independent trapezoid with a tapered side wall 113 of a desirable bottom angle 114, as shown in FIG. 3. The conditions and the recipes of the first material etching step may also be fine-tuned in order to obtain a different desirable bottom angles 114.

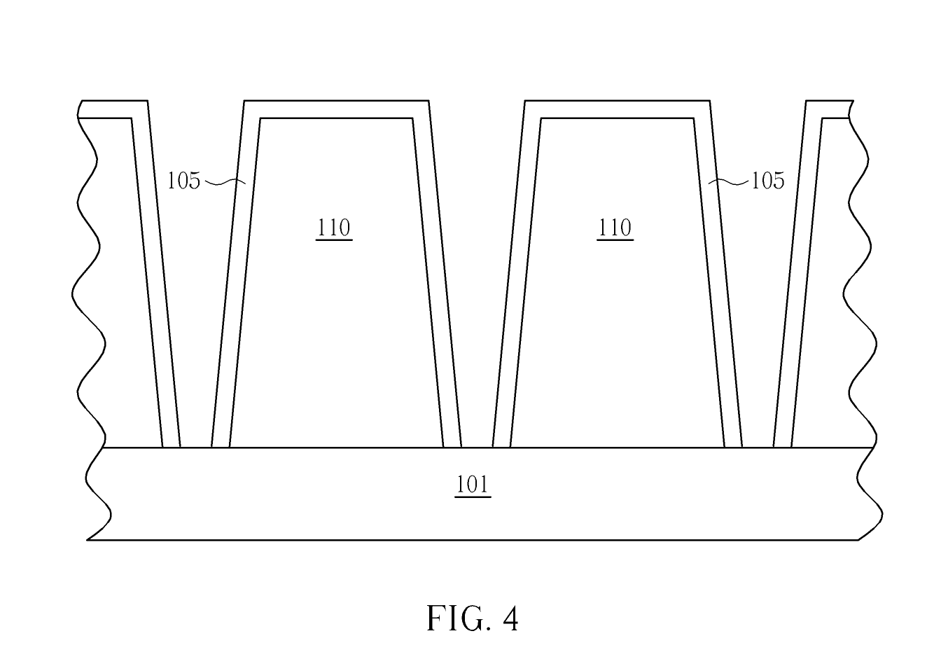

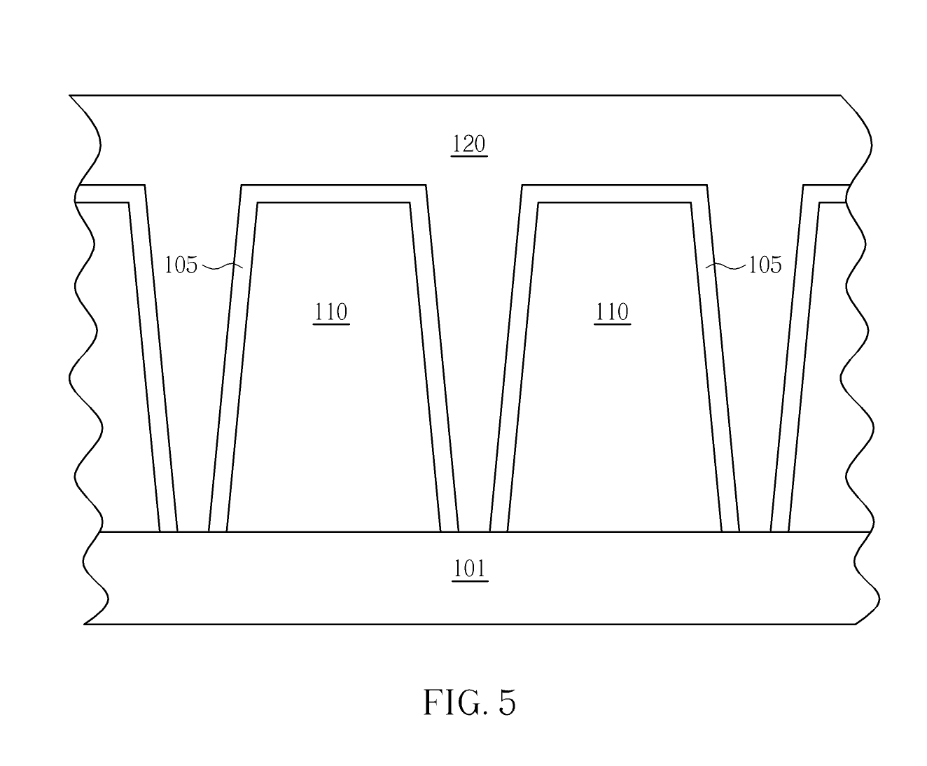

Second, as shown in FIG. 4, a cap layer 105 of a third material is optionally deposited to cover the tapered structures 110. The first material and the third material are mutually different. For example, the first material and the third material may have different etching selectivity. The third material may be SiN and the thickness of the cap layer 105 may be around 5 nm. It can shrink the CD of target material, and provide better interface between the target material and the container material. Then, as shown in FIG. 5, a target layer 120 of a second material is deposited to completely cover the exposed substrate 101 and to fill up the recess 117 disposed between the tapered structures 110. In other words, the previously formed tapered structures 110 act as containers to be the template of the target layer 120. When the cap layer 105 is present, the target layer 120 also covers the cap layer 105.

The first material, the second material and the third material are preferably different, or at least the first material, the second material and the third material must have substantially different etching selectivity. The second material may be a metal, a semi-conductive material or an insulating material. For example, the second material may be poly Si if gate structures of extremely small dimension are needed.

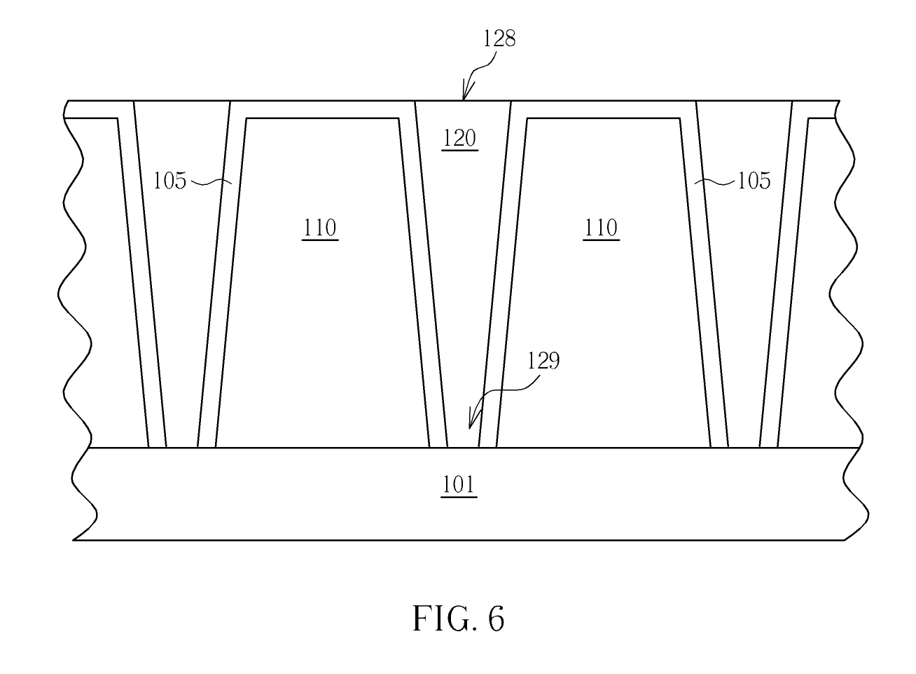

Later, as shown in FIG. 6, the excess second material of the target layer 120 on the tapered structures 110 may be partially removed by an etching step to expose the top side 111 of the tapered structures 110. For example, the etching step may be a break through etch.

Next, a trimming step is carried out for trimming the excess target layer 120. The trimming step may be a wet etching step to fine-tune the shape of the tapered structures 110 by adjusting an acid concentration. The tapered structures 110 are completely removed by the trimming step. When the cap layer 105 is present, the cap layer 105 is also completely removed.

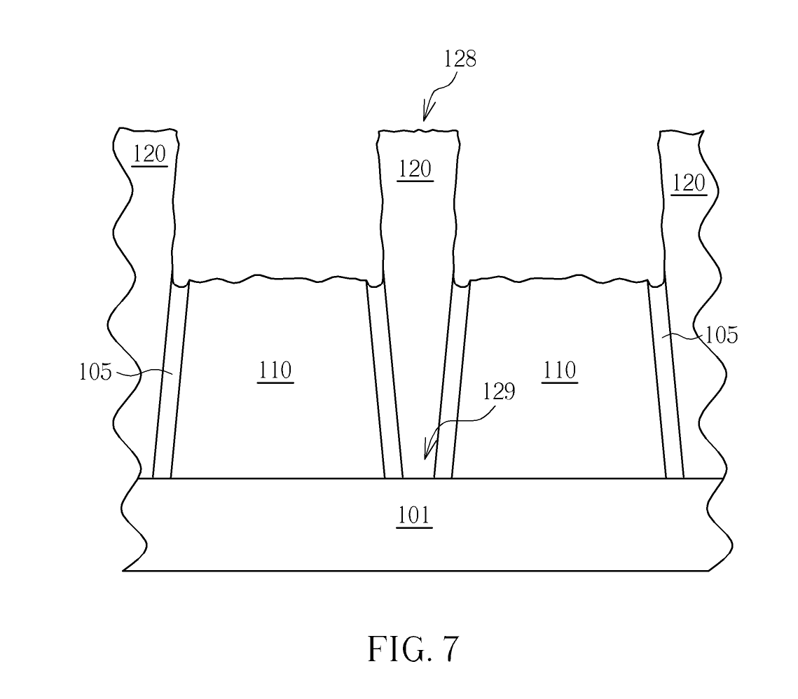

As shown in FIG. 7, since the first material, the second material and the third material have substantially different etching selectivity, the first material, the second material and the third material are removed discriminatively. The first material along with the third material is supposed to be more susceptible to the trimming step than the second material so the first material and the third material are much more easily removed than the second material. In the light of this reason, the wider top portion 128 of the target layer 120 is trimmed to be substantially similar to the smaller bottom portion 129 since the etchant in the trimming step contacts the wider top portion 128 longer than the smaller bottom portion 129 so the wider top portion 128 is much more trimmed than the smaller bottom portion 129.

For example, the tapered structures 110 are removed and the target layer 120 is trimmed by a highly selective recipe. For example, if the first material is an oxide, the second material is poly Si and the third material is SiN, the etching recipe may include C₄F₈ to discriminatively remove the first material, the second material and the third material and to partially expose the substrate 101 again.

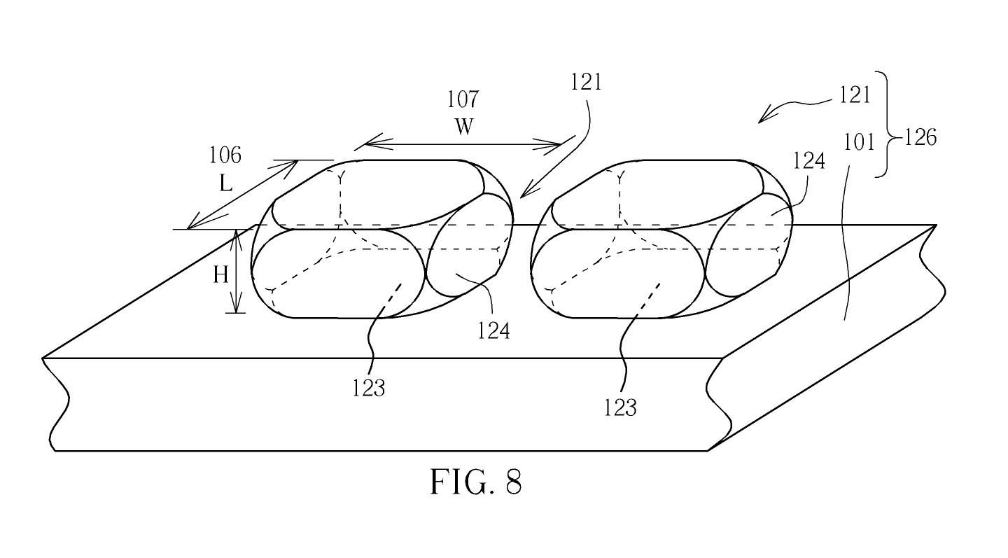

As shown in FIG. 8, after the tapered structures 110 are completely removed and the target layer 120 is well trimmed, the target layer 120 becomes multiple protrusions 121 disposed on the substrate 101 so a protuberant structure 126 is obtained. The present invention in a second aspect provides a protuberant structure 126 which has an extremely small dimension beyond the capability of the current photolithographic techniques on a substrate 101.

The protuberant structure 126 of the present invention includes a substrate 101 and a protrusion 121 disposed on the substrate 101. The protrusion 121 has a top side 122, a bottom side 123 and a vertical side wall 124 disposed between the top side 122 and the bottom side 123. Since the bottom part 119 of the recess 117 is more or less as wide as 33 nm before the trimming step, the bottom side 123 of the protrusion 121 after the trimming step must be not greater than 33 nm. Moreover, a protrusion 121 of an even smaller dimension is still possible to be formed as long as the first material etching step to define the size of the bottom part 119 of the recess 117 and the trimming step are respectively well controlled.

One feature of the protrusion 121 is at least one of the protuberant width W and the protuberant length L not greater than 33 nm because the top side 122 is similar to the bottom side 123 in dimension due to the vertical side wall 124. Another feature of the protrusion 121 resides in that the vertical side wall 124 has a rounded corner 127, as shown in FIG. 8.

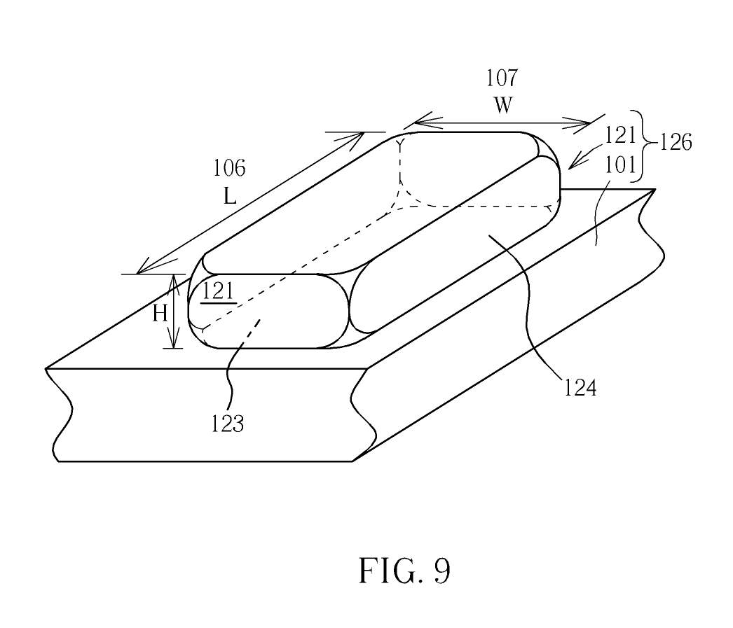

As shown in FIG. 9, the protrusion 121 may also have a protuberant length 106 at least 1 time greater than a protuberant width 107 or the protuberant length L is approximately equal to the protuberant width W as shown in FIG. 8. In another aspect, the protrusion 121 may have a protrusion height H at least half less than the protrusion width W.

In one embodiment of the present invention, the protuberant structure 126 of the present invention may be a gate structure for use in a semiconductor structure, such as nano-flash. The size of the protuberant structure 126 of the present invention is so small that it is not able to be formed by traditional photolithographic methods. A semiconductor device of a smaller size is critical in increasing the element density. The protuberant structure 126 of the present invention may also be used to form a sensor in a MEMS (microelectromechanical structure).

Those skilled in the art will readily observe that numerous modifications and alterations of the device and method may be made while retaining the teachings of the invention.

What is claimed is:

1. A protuberant structure, comprising:
a substrate; and
a protrusion disposed on said substrate and having a vertical side wall with a rounded corner, a protuberant width and a protuberant length, wherein at least one of said protuberant width and said protuberant length is not greater than 33 nm.

2. The protuberant structure of claim 1, wherein said substrate is a semi-conductive material.

3. The protuberant structure of claim 1, wherein said protrusion comprises a material selected from a group consisting of a metal, a semi-conductive material and an insulating material.

4. The protuberant structure of claim 1, wherein said protuberant length is at least 1 time greater than said protuberant width.

5. The protuberant structure of claim 1, wherein said protuberant length approximately equals said protuberant width.

6. The protuberant structure of claim 1, wherein said protrusion having a protuberant height at least half less than said protuberant width.

7. The protuberant structure of claim 1, wherein said protrusion forms a gate structure.

8. The protuberant structure of claim 1, wherein said protrusion forms a MEMS (microelectromechanical) structure.

9. The protuberant structure of claim 1, further comprising:
a plurality of said protrusions disposed on said substrate.

10. A method for forming a protuberant structure, comprising:
providing a substrate and a plurality of tapered structures of a first material disposed on said substrate and segregated by a pre-determined distance;
forming a target layer of a second material to cover said substrate and said tapered structures, wherein said first material and said second material are different;
performing an etching step to partially remove said target layer to expose said tapered structures; and
performing a trimming step to completely remove said tapered structures and to partially remove said target layer to form a protrusion which has a vertical side wall, a rounded corner, a protuberant width and a protuberant length, wherein said target layer is more susceptible to said trimming step than said tapered structures and at least one of said protuberant width and said protuberant length is not greater than 33 nm.

11. The method for forming a protuberant structure of claim 10, further comprising:
forming a layer of said first material on said substrate;
partially removing said first material by a first material etching step in the presence of a mask to form at least one recess which has an opening greater than the bottom of said recess and is disposed between said tapered structures.

12. The method for forming a protuberant structure of claim 11, wherein the width of the bottom of said recess is not greater than 33 nm.

13. The method for forming a protuberant structure of claim 11, wherein the width of the bottom of said recess is greater than said protuberant width.

14. The method for forming a protuberant structure of claim 10, further comprising:
forming a cap layer of a third material to cover said tapered structures, wherein said first material, said second material and said third material are mutually different.

15. The method for forming a protuberant structure of claim 14, further comprising:
performing said trimming step to completely remove said cap layer.

16. The method for forming a protuberant structure of claim 14, wherein said cap layer has a thickness around 5 nm.

17. The method for forming a protuberant structure of claim 10, wherein said protrusion comprises a material selected from a group consisting of a metal, a semi-conductive material and an insulating material.

18. The method for forming a protuberant structure of claim 10, wherein said protuberant length is at least 1 time greater than said protuberant width.

19. The method for forming a protuberant structure of claim 10, wherein said protuberant length approximately equals said protuberant width.

20. The method for forming a protuberant structure of claim 10, wherein said protrusion having a protuberant height and said protuberant height is at least half less than said protuberant width.
